(19) United States
(12) Patent Application Publication
(10) Pub. No.: US 2002/0047209 A1
(43) Pub. Date: Apr. 25, 2002

(54) Method for forming contact hole for dual damascene interconnection of semiconductor device and resultant structure

(76) Inventors: Suk Joo Lee, Kyungki-do (KR); Hee Hong Yang, Kyungki-do (KR); Jeong Lim Nam, Kyungki-do (KR)

Correspondence Address: JONES VOLENTINE, P.L.L.C., Suite 150, 12200 Sunrise Valley Drive, Reston, VA, 20191, US

(21) Appl. No.: 09/969,993

(22) Filed: Oct. 4, 2001

(30) Foreign Application Priority Data
Oct. 20, 2000 (KR) 2000-61987

(51) Int. Cl. H01L 21/44; H01L 23/48; H01L 29/40

(52) U.S. Cl. 257/774; 438/629; 438/675

(57) ABSTRACT

A method of forming a contact hole for a dual damascene interconnection of a semiconductor device includes forming a first photoresist layer pattern on an insulating layer of a semiconductor substrate, the first photoresist layer pattern having a first opening with a first width. A groove having the first width to a prescribed depth of the insulating layer is formed by performing an etching process using the first photoresist layer pattern as an etch mask. A second photoresist layer pattern on the insulating layer having the groove therein is formed. The second photoresist layer has a second opening with a second width, wherein the second width is substantially equal to or larger than the first width of the groove. A contact hole exposing the semiconductor substrate is formed by performing an etching process using the second photoresist layer pattern as an etch mask.

### CROSS-REFERENCE TO RELATED APPLICATION

The present application claims priority under 35 U.S.C. §119 to Korean Patent Application No. 00-61987 filed on Oct. 20, 2000, the entire contents of which are hereby incorporated by reference.

### BACKGROUND OF THE INVENTION

1. Field of the Invention

The present invention relates to a method for forming a contact hole of a semiconductor device, and more particularly, to a method for forming a contact hole for a dual damascene interconnection of a semiconductor device, and a resultant structure.

2. Description of the Related Art

A dual damascene process is currently widely used in forming metallic interconnections in semiconductor integrated circuit devices. The dual damascene process usually includes forming a contact hole which defines an interconnection area and filling the interconnection area with a conductive substance.

FIG. 1 is a layout showing a contact hole for a dual damascene interconnection of a conventional semiconductor device. FIGS. 2A through 2C are sectional views taken along the line II-II′ of FIG. 1, illustrating a method of forming a contact hole for a dual damascene interconnection of a conventional semiconductor device.

As illustrated in FIG. 2A, an insulating layer, for example, an oxide layer 110 is formed on a semiconductor substrate 100, and a photoresist layer pattern 120 is formed on the oxide layer 110. The photoresist layer pattern 120 has an opening with a width of “M”. Next, an etching process is performed using the photoresist layer pattern as an etch mask, and then an oxide layer pattern 111 having a groove 150 with a width of “M” is formed as illustrated in FIG. 2B. Then a photoresist layer pattern 130 is formed on the oxide layer pattern 111. The photoresist layer pattern 130 has an opening with a width of “C”, which exposes a portion of the groove 150 in the oxide layer pattern 111. As illustrated in FIG. 2C, an etching process is performed using the photoresist layer pattern 130 as an etch mask and then an oxide layer pattern 112 having a groove 150 with a width of “M” and a contact hole 160 having a width of “C” within the groove 150 is formed. After the formation of the oxide layer pattern 112, the photoresist layer pattern 130 is removed, and then the contact hole 160 and the groove 150 are filled with a metal layer 140. In FIG. 2C, the distance “O” designates the distance between the edges of the groove 150 and the contact hole 160.

In performing a damascene interconnection process, the photoresist layer pattern 130 having an opening with a width of “C” is formed on the oxide layer pattern 111 in which a groove 150 is formed, to form the contact hole 160. According to the position of the opening formed by the photoresist layer pattern 130, sometimes the surface of the oxide layer pattern 111 is not exposed. This problem will be described in detail as follows.

FIGS. 3 through 4 are diagrams illustrating the above problem in a conventional method of forming a contact hole for a dual damascene interconnection. The same reference numerals in FIGS. 2A through 2C, 3, and 4 represent the same elements.

In FIG. 3, a photoresist layer 130′ is formed on an oxide layer pattern 111 to form the photoresist layer pattern 130 illustrated in FIG. 2B. Light is applied to a portion of the surface of the photoresist layer 130′ by using a mask pattern 300. Here, the above mask pattern 300 has an opening for forming a first contact hole 301 away from one side wall of the oxide layer pattern 111 and an opening for a second contact hole close to the other side wall of the oxide layer pattern 111. The thickness “d” of the photoresist layer 130′ formed in the groove 150 of the oxide layer pattern 111 is larger than those of the photoresist layer 130′ on the surface of the oxide layer pattern 111 out of the groove 150, so that as light penetrates further into the photoresist 130′ in the groove 150, the intensity of light gets weaker. That is to say, the light intensity 321 at the surface of the photoresist layer 130′ is strongest, and the light intensity 322 at half the depth of the photoresist layer is weaker than the light intensity on the surface of the photoresist layer. The light intensity 323 at the bottom of the photoresist layer is weakest.

Thus, if the photoresist layer pattern is formed by exposing the photoresist layer to light and developing it, a first contact hole which does not expose the surface of the oxide layer pattern 111 is formed, because a portion having weak light intensity, such as the bottom of the photoresist layer 130′ is not developed. FIG. 4 shows a first contact hole 301′ which is not open. On the other hand, a second contact hole 302′ close to a side wall of the oxide layer pattern 111 is formed to the extent that the oxide layer pattern 111 is partially exposed, because the light reflected by the side wall of the oxide layer pattern 111 compensates for the lack of light intensity at the bottom of the photoresist layer 130′. FIG. 4 shows a photoresist layer pattern 135 having a first contact hole 301′ which is not completely open and a second contact hole 302′ which is open. Neither of the contact holes are satisfactory.

### SUMMARY OF THE INVENTION

It is an object of the present invention to provide a method of forming a contact hole for a dual damascene interconnection of a semiconductor device and a resultant structure which substantially overcomes at least the problem stated above.

The above and other objects of the present invention may be realized by providing a method of forming a contact hole for a dual damascene interconnection of a semiconductor device including forming a first photoresist layer pattern on an insulating layer of a semiconductor substrate, the first photoresist layer pattern having a first opening with a first width. A groove having the first width to a prescribed depth of the insulating layer is formed by performing an etching process using the first photoresist layer pattern as an etch mask. A second photoresist layer pattern on the insulating layer having the groove therein is formed. The second photoresist layer has a second opening with a second width, wherein the second width is substantially equal to or larger than the first width of the groove. A contact hole exposing the semiconductor substrate is formed by performing an etching process using the second photoresist layer pattern as an etch mask. The insulating layer is preferably an oxide layer and the etching process is also preferably a dry etch.

The above and other objects of the present invention may be realized by providing an interconnection structure for a dual damascene interconnection of a semiconductor substrate including contact hole exposing the semiconductor substrate, the contact hole being in an insulating layer on the semiconductor substrate, and a groove in the insulating layer, the groove being further from the semiconductor substrate than the contact hole, wherein a width of the contact hole is substantially equal to or greater than a width of the groove.

These and other objects of the present invention will become more readily apparent from the detailed description given hereinafter. However, it should be understood that the detailed description and specific examples, while indicating the preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The foregoing and other objects, aspects and advantages will be described with reference to the following drawings.

FIG. 1 is a layout illustrating a conventional contact hole for a dual damascene interconnection of a semiconductor device.

FIGS. 2A through 2C are sectional views taken along the line II-II′ of FIG. 1, illustrating a conventional method of forming a contact hole for a dual damascene interconnection of a semiconductor device.

FIG. 3 is a diagram illustrating a problem in a conventional method of forming a contact hole for a dual damascene interconnection.

FIG. 4 is a diagram showing a contact hole formed by a conventional method of forming a contact hole for a dual damascene interconnection.

FIG. 5 is a layout showing a contact hole for a dual damascene interconnection of a semiconductor device according to a first embodiment of the present invention.

FIGS. 6A through 6D are sectional views taken along the line VI-VI′ of FIG. 5, illustrating a method of forming a contact hole for a dual damascene interconnection of a semiconductor device according to the first embodiment of the present invention.

FIGS. 7A through 7D are sectional views illustrating a method of forming a contact hole for a dual damascene interconnection of a semiconductor device according to the second embodiment of the present invention.

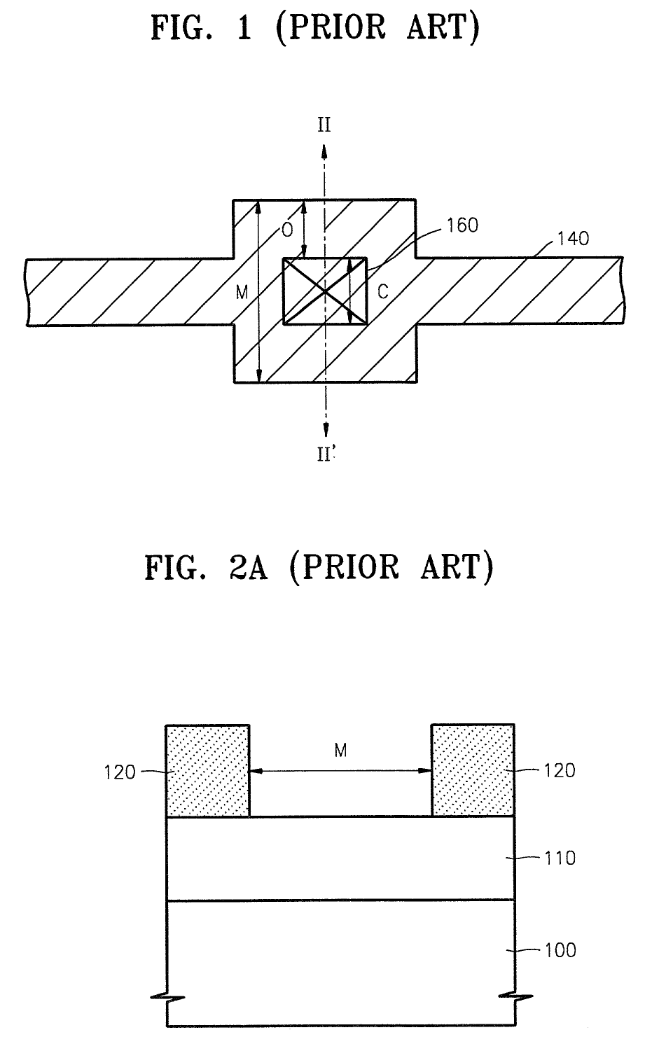

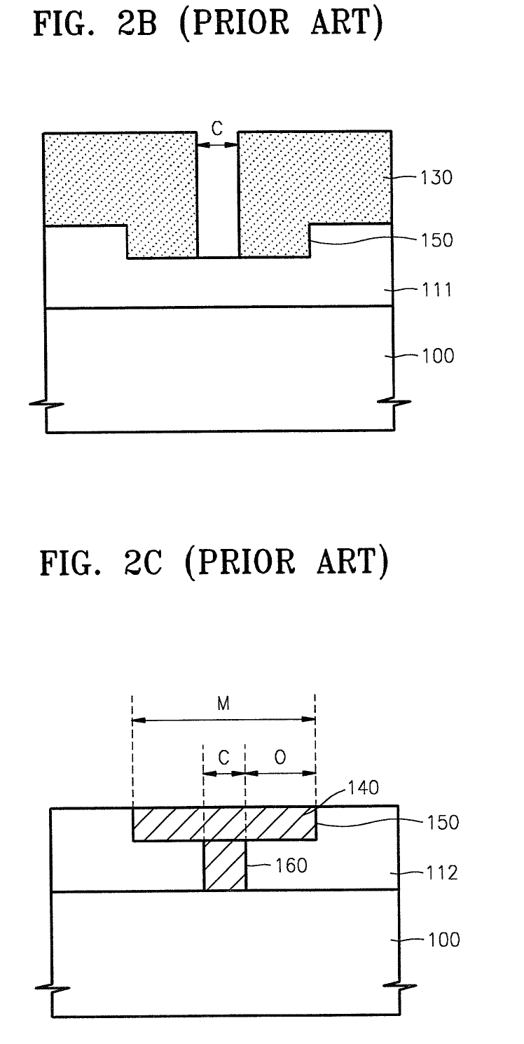

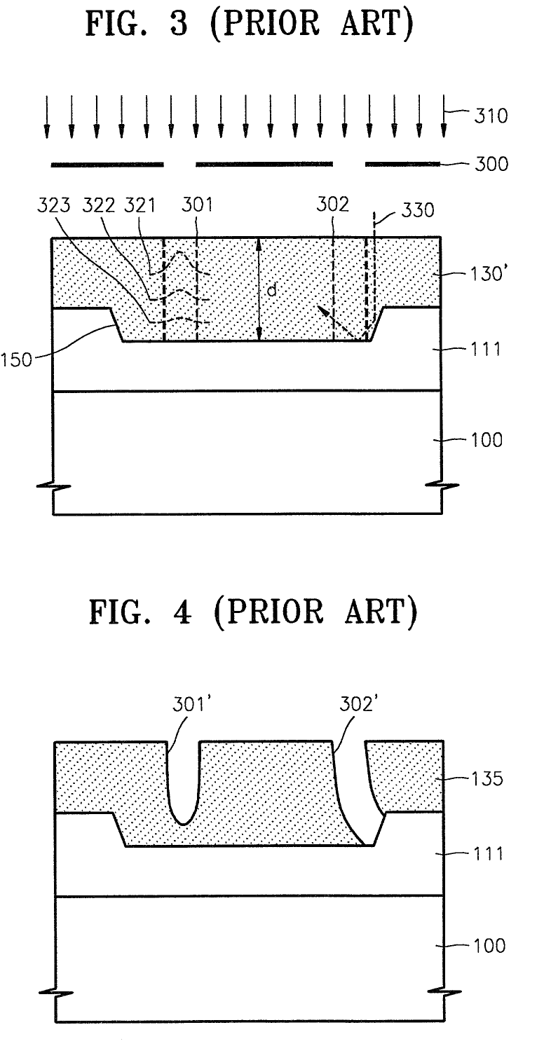

### DETAILED DESCRIPTION OF THE PRESENT INVENTION

Hereinafter, preferred embodiments of the present invention will be described in detail with reference to the attached drawings. This invention may be embodied in many different forms and should not be construed as being limited to the embodiments set forth herein; rather, these embodiments are provided so that this disclosure will be thorough and complete, and will fully convey the concept of the invention to those skilled in the art.

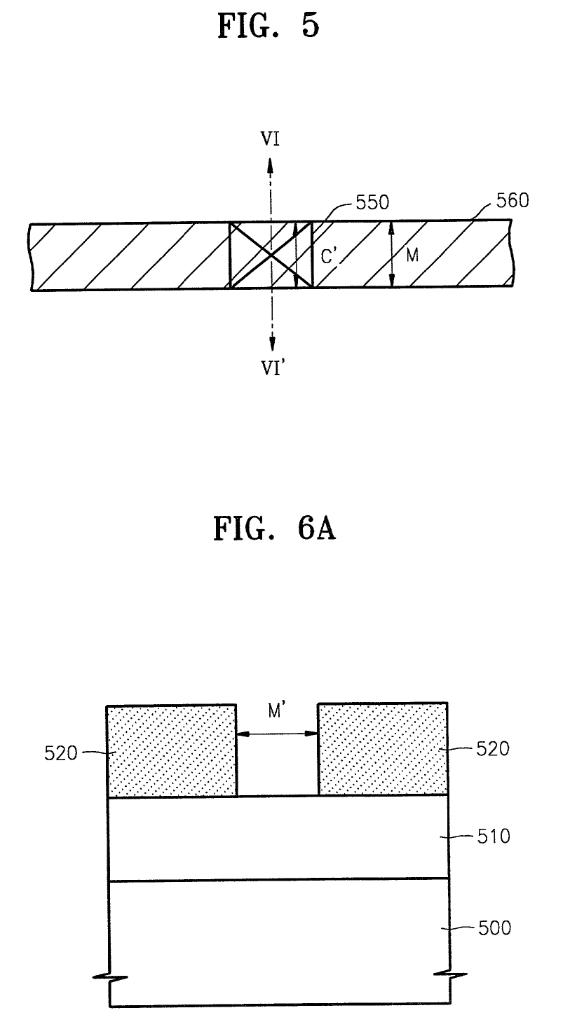

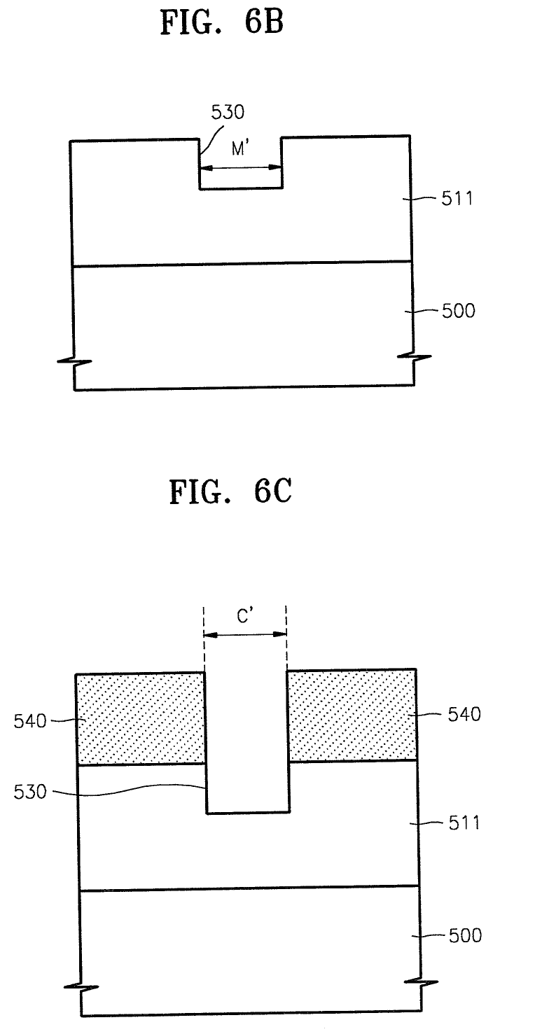

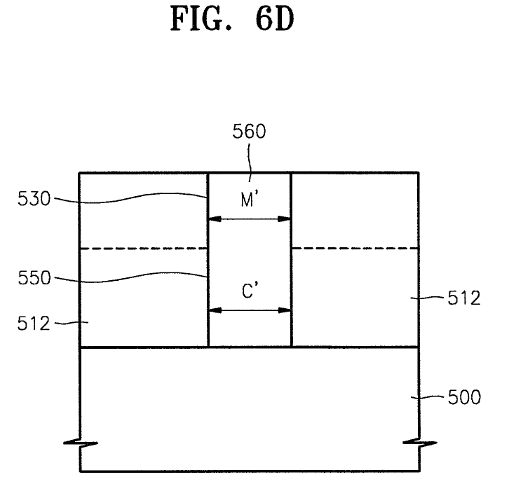

FIG. 5 is a layout showing a contact hole for a dual damascene interconnection of a semiconductor device according to a first embodiment of the present invention. FIGS. 6A through 6D are sectional views taken along the line VI - VI′ of FIG. 5, illustrating a method of forming a contact hole for a dual damascene interconnection of a semiconductor device according to the first embodiment of the present invention.

As illustrated in FIG. 6A, after an insulating layer 510, such as an oxide layer, is formed on a semiconductor substrate 500, a photoresist layer pattern 520 is formed on the insulating layer 510. A metallic layer may also be formed between the semiconductor substrate 500 and the insulating layer 510. The photoresist layer pattern 520 has an opening with a width of “M”, and the opening can be formed by using a conventional photolithographic method.

As illustrated in FIG. 6B, an insulating layer pattern 511 having a groove 530 with a width of “M” is formed by performing an etching process, such as a dry etch, where the photoresist layer pattern 520 of FIG. 6a is used as an etch mask. After the formation of the insulating layer pattern 511, the photoresist layer pattern 520 is removed.

As illustrated in FIG. 6C, a photoresist layer pattern 540 is formed again on the insulating layer pattern 511. The photoresist layer pattern 540 has an opening with a width of “C” which entirely exposes the bottom of the groove 530 in the insulating layer pattern 511. Therefore, the width C′ of the opening of the photoresist layer pattern 540 is substantially the same as the width M′ of the groove 530 of the insulating layer pattern 511.

To form this photoresist layer pattern 540, a photoresist layer is formed on the insulating layer pattern 511. Next, light is applied to a portion of the photoresist layer by using a mask layer pattern which has a prescribed opening, that is to say, an opening with the same width as the width M′ of the groove 530 of the insulating layer pattern 511. In this case, the photoresist layer in the groove 530 is thicker than the photoresist layer in other places. Thus, again the weakest light intensity is at the bottom of the photoresist layer pattern. However, the edge of an area exposed to light is very close to the side wall of the groove 530, so the light reflected by the side wall can compensate for the lack of light intensity at the bottom of the photoresist layer. Therefore, during a development process, the area exposed to light can be sufficiently removed, and the photoresist layer pattern 540 which completely exposes the groove in the insulating layer pattern 511 is formed.

As illustrated in FIG. 6D, after performing an etching process such as a dry etch, using the photoresist layer pattern 540 as an etch mask, an insulating layer pattern 512 which has a groove 530 and a contact hole 550 with the same width C′ as the width M′ of the groove 530, is formed. Next, the photoresist layer pattern 540 is removed, and the contact hole and the groove are filled with a metallic layer 560. Finally, a damascene interconnection is completed. In FIG. 6d, dotted lines are used to denote the boundary between the groove 530 and the contact hole 550.

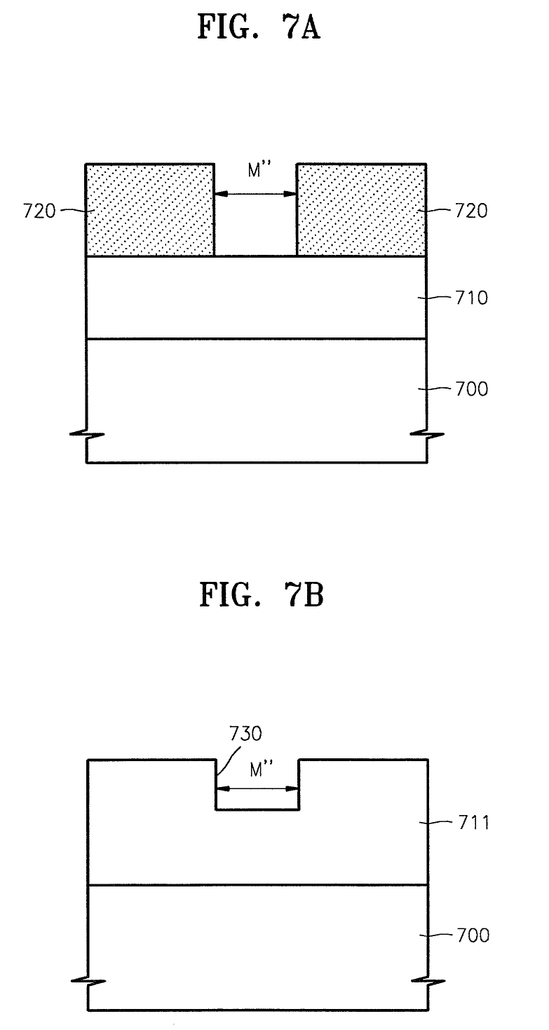

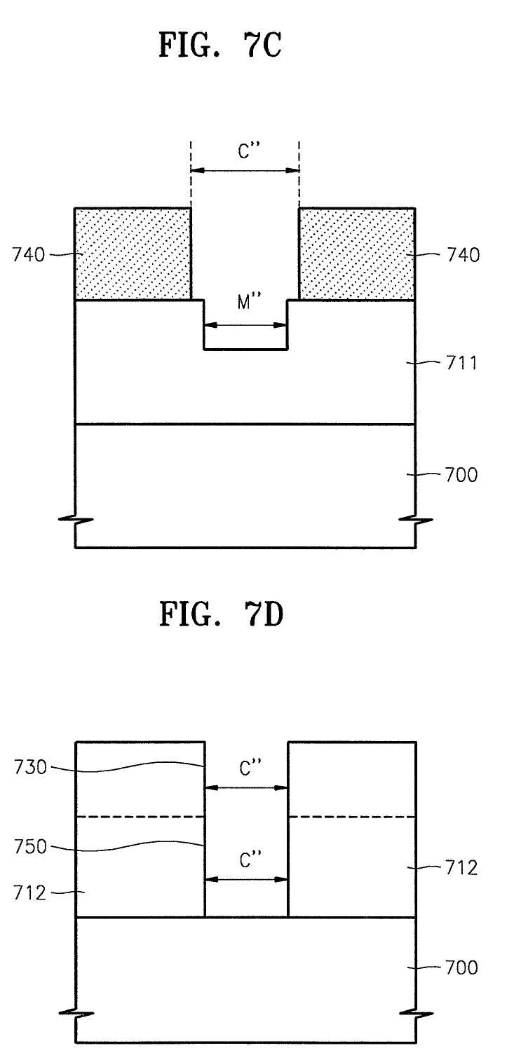

FIGS. 7A through 7D are sectional views illustrating a method of forming a contact hole for a dual damascene interconnection of a semiconductor device according to a second embodiment of the present invention.

As illustrated in FIG. 7A, after an insulating layer 710, such as an oxide layer, is formed on a semiconductor substrate 700, a photoresist layer pattern 720 is formed on the insulating layer 710. A metallic layer may also be formed between the semiconductor substrate 700 and the insulating layer 710. The photoresist layer pattern 720 has an opening with a width of “M″” which can be formed by using a conventional lithographic method.

As illustrated in FIG. 7B, an insulating layer pattern 711 having a groove 730 with a width of “M″” is formed by performing an etching process such as a dry etching process, where the photoresist layer pattern 720 of FIG. 7A is used as an etch mask. After the formation of the insulating layer pattern 711, the photoresist layer pattern 720 is removed.

As illustrated in FIG. 7C, a photoresist layer pattern 740 is formed again on the insulating layer pattern 711. The photoresist layer pattern 740 has an opening with a width of “C″“ which entirely exposes the bottom of the groove 730 in the insulating layer pattern 711. And the width C″ of the opening of the photoresist layer pattern 740 is larger than the width M″ of the groove 730 of the insulating layer pattern 711.

To form this photoresist layer pattern 740, a photoresist layer is formed on the insulating layer pattern 711. Next, light is applied to a portion of the photoresist layer by using a mask layer pattern which has a prescribed opening, i.e., an opening with the width larger than the width M″ of the groove 730 of the insulating layer pattern 711. In this case, the photoresist layer in the groove 730 is thicker than the photoresist layer in other places, Thus, again the weakest light intensity is at the bottom of the photoresist layer pattern. However, the edge of an area exposed to light overlaps with the side wall of the groove 730, so light reflected by the side wall can compensate for the lack of light intensity at the bottom of the photoresist layer. Therefore, during a development process, the area exposed to light can be sufficiently removed, and the open photoresist layer pattern 740 which completely exposes the groove in the insulating layer pattern 711 is formed.

As illustrated in FIG. 7D, after performing an etching process such as a dry etching process using the photoresist layer pattern 740 as an etch mask, an insulating layer pattern 712 which has a groove 730 and a contact hole 750 with the width C″ larger than the width M″ of the groove 730, is formed. Next, the photoresist layer pattern 740 is removed, and the contact hole and the groove are filled with a metallic layer (not shown). Finally, a damascene interconnection is completed. In FIG. 7D, dotted lines are used to denote the boundary between the groove 730 and the contact hole 750.

As described above, in the method of forming a contact hole for a dual damascene interconnection of a semiconductor device according to the present invention, the side wall of a groove is fully or partially included in the area exposed to light. The light reflected by the side wall of the groove can then compensate for the lack of light intensity at the bottom of a photoresist layer, thereby forming an open contact hole.

While the present invention has been particularly shown and described with reference to preferred embodiments thereof, it will be understood by those skilled in the art that various changes in form and details may be made therein without departing from the spirit and scope of the invention.

What is claimed is:

1. A method of forming a contact hole for a dual damascene interconnection of a semiconductor device, comprising:
forming a first photoresist layer pattern on an insulating layer of a semiconductor substrate, the first photoresist layer pattern having a first opening with a first width;
forming a groove having the first width to a prescribed depth of the insulating layer by performing an etching process using the first photoresist layer pattern as an etch mask;
forming a second photoresist layer pattern on the insulating layer having the groove therein, the second photoresist layer having a second opening with a second width, wherein the second width is substantially equal to or larger than the first width of the groove;
forming a contact hole exposing the semiconductor substrate by performing an etching process using the second photoresist layer pattern as an etch mask.

2. The method of claim 1, wherein the insulating layer is an oxide layer.

3. The method of claim 1, wherein the etching process is a dry etch.

4. The method of claim 1, further comprising, before said forming the second photoresist layer pattern, removing the first photoresist layer pattern.

5. The method of claim 1, further comprising removing the second photoresist layer pattern.

6. An interconnection structure for a dual damascene interconnection of a semiconductor substrate comprising:
a contact hole exposing the semiconductor substrate, the contact hole being in an insulating layer on the semiconductor substrate; and
a groove in the insulating layer, the groove being further from the semiconductor substrate than the contact hole, wherein a width of the contact hole is substantially equal to or greater than a width of the groove.

7. The structure of claim, wherein the insulating layer is an oxide layer.
